(19) United States
(12) Patent Application Publication
(10) Pub. No.: US 2021/0202764 A1
(43) Pub. Date: Jul. 1, 2021

(54) SEPARATE ABSORPTION CHARGE AND MULTIPLICATION AVALANCHE PHOTODIODE STRUCTURE AND METHOD OF MAKING SUCH A STRUCTURE

(71) Applicant: GLOBALFOUNDRIES U.S. Inc., Santa Clara, CA (US)

(72) Inventors: Ajey Poovannummoottil Jacob, Watervliet, NY (US); Yusheng Bian, Ballston, NY (US)

(21) Appl. No.: 16/729,930

(22) Filed: Dec. 30, 2019

(51) Int. Cl. H01L 31/0352; H01L 31/028; H01L 31/105; H01L 31/107; H01L 31/18

(52) U.S. Cl. CPC H01L 31/035218; H01L 31/028; H01L 31/1804; H01L 31/1075; H01L 31/105

(57) ABSTRACT

One illustrative photodiode disclosed herein includes an N-doped anode region, an N-doped impact ionization region positioned above the N-doped anode region and at least one P-doped charge region positioned above the N-doped impact ionization region. In this example, the photodiode also includes a plurality of quantum dots embedded within the at least one P-doped charge region and a P-doped cathode region positioned above the at least one P-doped charge region.

### BACKGROUND

### Field of the Invention

The present disclosure generally relates to various novel embodiments of a separate absorption charge and multiplication (SACM) avalanche photodiode (APD) structure and various methods of making such a structure.

### Description of the Related Art

A need for greater bandwidth in fiber optic network links is widely recognized. The volume of data transmissions has seen a dramatic increase in the last decade. This trend is expected to grow exponentially in the near future. As a result, there exists a need for deploying an infrastructure capable of handling this increased volume and for improvements in system performance. Fiber optics communications have gained prominence in telecommunications, instrumentation, cable TV, network, and data transmission and distribution. A fiber optics communication system or link includes a photo detector element. The function of the photo detector element in a fiber optic communication system is to convert optical power into electrical voltage or current. The most common photo detector used in fiber applications is the photodiode.

There are two options for the photodiode element: a standard P-I-N diode structure (positive/intrinsic/negative type conductivity) and the avalanche photodiode (APD). The type of semiconductor photodiode commonly used for fiber optics applications has a reverse bias p-n junction. Both types of photodiodes are instantaneous photon-to-electron converters where absorbed photons generate hole-electron pairs to produce an electric current. The P-I-N photodiode and the avalanche photodiode are actually modified p-n junction devices with additional layers at differing doping levels that produce either more efficient quantum conversion or avalanche gain through ionization. A photon is absorbed in a relatively high E (electric) field region, where an electron-hole pair is created. This will produce current in the detector circuit. Although an avalanche photodiode requires higher operating voltages, which must be compensated for with respect to temperature shifts, the internal gain of the avalanche photodiode provides a significant enhancement in receiver sensitivity and can be a key enabler in the manufacturing of high sensitivity optical receivers for high speed applications. Avalanche photodiodes exhibit internal gain through avalanche multiplication. In the presence of sufficiently high electric field intensity, an initial photon-induced carrier can seed an avalanche process in which carriers obtain enough energy from the electric field to generate additional carrier pairs through impact ionization. By such an effect, a single photon can give rise to tens or even hundreds of carriers which contribute to the resulting photo current. Moreover, an avalanche photodiode typically provides a significant increase in the receiver signal-to-noise ratio (SNR). The increased SNR is particularly attractive at higher frequencies where increased amplifier noise is unavoidable.

There is a need to produce a novel avalanche photodiode that is efficient to manufacture and may produce benefits with respect to the optical system or link in which such avalanche photodiodes are employed. The present disclosure is generally directed to a separate absorption charge and multiplication (SACM) avalanche photodiode (APD) structure and various methods of making such a structure.

### SUMMARY

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

The present disclosure is directed to various novel embodiments of a separate absorption charge and multiplication (SACM) avalanche photodiode (APD) structure and various methods of making such a structure. One illustrative photodiode disclosed herein includes an N-doped anode region, an N-doped impact ionization region positioned above the N-doped anode region and at least one P-doped charge region positioned above the N-doped impact ionization region. In this example, the photodiode also includes a plurality of quantum dots embedded within the at least one P-doped charge region and a P-doped cathode region positioned above the at least one P-doped charge region.

### BRIEF DESCRIPTION OF THE DRAWINGS

The disclosure may be understood by reference to the following description taken in conjunction with the accompanying drawings, in which like reference numerals identify like elements, and in which:

FIGS. 1-14 depict various novel embodiments of a separate absorption charge and multiplication (SACM) avalanche photodiode (APD) structure and various methods of making such a structure. The drawings are not to scale.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase. As will be readily apparent to those skilled in the art upon a complete reading of the present application, the presently disclosed method may be applicable to a variety of products, including, but not limited to, logic products, memory products, etc. With reference to the attached figures, various illustrative embodiments of the methods and devices disclosed herein will now be described in more detail. The various components, structures and layers of material depicted herein may be formed using a variety of different materials and by performing a variety of known process operations, e.g., chemical vapor deposition (CVD), atomic layer deposition (ALD), a thermal growth process, spin-coating techniques, masking, etching, etc. The thicknesses of these various layers of material may also vary depending upon the particular application.

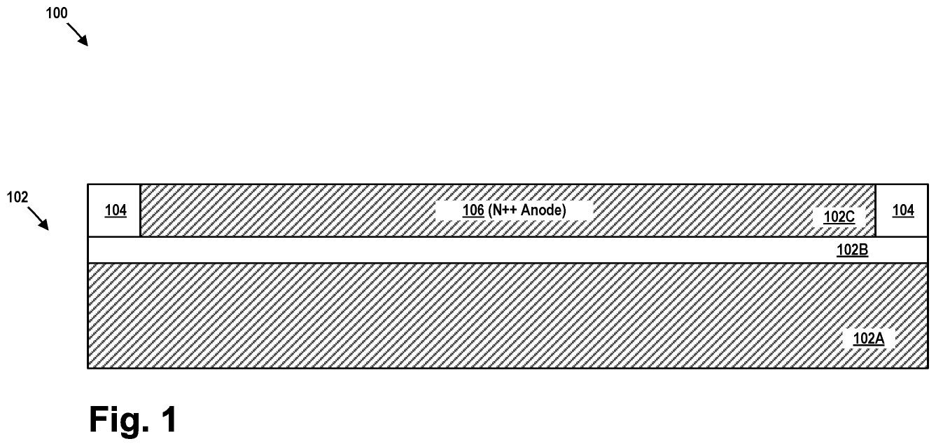

FIGS. 1-14 depict various novel embodiments of a separate absorption charge and multiplication (SACM) avalanche photodiode (APD) structure 100 and various methods of making such a structure. In the examples depicted herein, the photodiode structure 100 will be formed above a semiconductor substrate 102. The substrate 102 may have a variety of configurations, such as a semiconductor-on-insulator (SOI) shown in FIG. 1. Such an SOI substrate 102 includes a base semiconductor layer 102A, a buried insulation layer 102B positioned on the base semiconductor layer 102A and an active semiconductor layer 102C positioned above the buried insulation layer 102B, wherein the photodiode structure 100 will be formed in and above the active semiconductor layer 102C. Alternatively, the substrate 102 may have a simple bulk configuration. The substrate 102 may be made of silicon or it may be made of semiconductor materials other than silicon. Thus, the terms “substrate” or “semiconductor substrate” should be understood to cover all semiconductor materials and all forms of such materials.

FIG. 1 is a cross-sectional view of one illustrative embodiment of a photodiode structure 100 disclosed herein at an early stage of fabrication. More specifically, FIG. 1 depicts the photodiode structure 100 after an isolation structure 104 (e.g., a shallow trench isolation structure) has been formed in the active layer 102C and after an ion implantation process was performed to form an N++ doped anode region 106 in the active layer 102C. The maximum concentration of dopant atoms in the N++ doped anode region 106 may vary depending upon the particular application, e.g., 1E20-1E23 ions/cm³. The vertical depth of the N++ doped anode region 106 and the location of the peak concentration of dopant atoms in the N++ doped anode region 106 within the vertical thickness of the active layer 102C may also vary depending upon the particular application. In one illustrative example, the vertical depth of the N++ doped anode region 106 may be about equal to the vertical thickness of the active layer 102C and the peak concentration of dopant atoms may be located at approximately mid-thickness of the active layer 102C. The N++ doped anode region 106 may be doped with any species of N-type dopant, e.g., arsenic, phosphorus, etc. The N++ doped anode region 106 may be formed by performing masking and ion implantation processes that are well known to those skilled in the art. When viewed from above, the N++ doped anode region 106 (as well as the overall photodiode structure 100) may have any desired configuration, e.g., square, rectangular, circular, etc., and the physical dimensions of the N++ doped anode region 106 (and the other components of the photodiode structure 100) may also vary depending upon the particular application. In one example, the N++ doped anode region 106 acts as a waveguide through which light passes and couples into the photodetector through evanescent coupling.

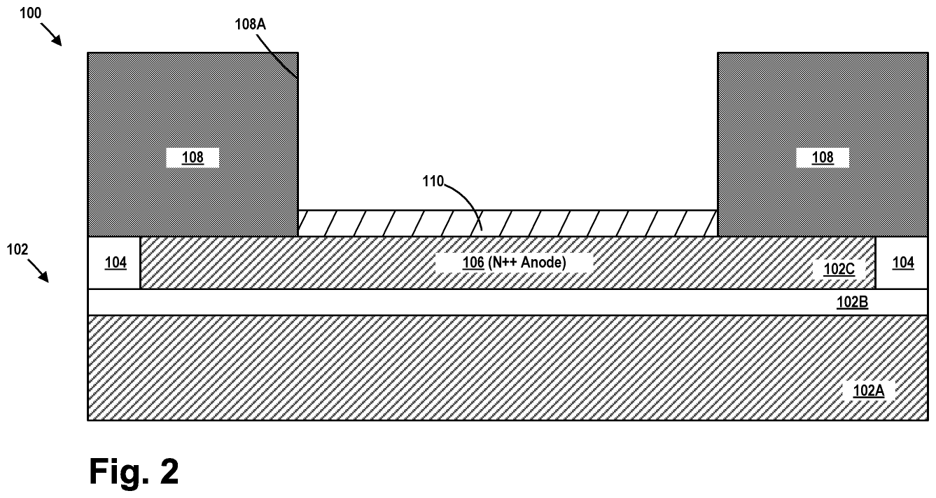

FIG. 2 depicts the photodiode structure 100 after several process operations were performed. First, a patterned mask layer 108, with an opening 108A defined therein, was formed above the substrate 102. The patterned mask layer 108 may take a variety of forms and may be comprised of a variety of different materials e.g., silicon nitride, silicon dioxide, etc. The patterned mask layer 108 may be formed by performing known deposition, photolithography and etching techniques. Next, an N+ doped impact ionization region 110 (i.e., a multiplication region) was formed above the N++ doped anode region 106. In one illustrative embodiment, the N+ doped impact ionization region 110 was formed on and in physical contact with an upper surface of the N++ doped anode region 106. The N+ doped impact ionization region 110 may be formed by performing traditional epitaxial semiconductor growth processes and it may be formed to any desired thickness, e.g., 5-50 nm. The N+ doped impact ionization region 110 may be comprised of a variety of different materials, e.g., silicon, silicon germanium, etc. In one illustrative process flow, the N+ doped impact ionization region 110 may be doped with an N-type dopant as it is grown, i.e., it may be doped in situ. In other applications, the epi semiconductor material for the N+ doped impact ionization region 110 may be initially formed as substantially un-doped epi material and thereafter doped with the appropriate dopant atoms by performing one or more ion implantation processes. The maximum concentration of dopant atoms in the N+ doped impact ionization region 110 may vary depending upon the particular application, e.g., 1E18-1E20 ions/cm³. The location of the peak concentration of dopant atoms within the vertical thickness of the N+ doped impact ionization region 110 may also vary depending upon the particular application. In one illustrative example, the peak concentration of dopant atoms may be located at approximately mid-thickness of the N+ doped impact ionization region 110. The N+ doped impact ionization region 110 may be doped with any species of N-type dopant, e.g., arsenic, phosphorus, etc.

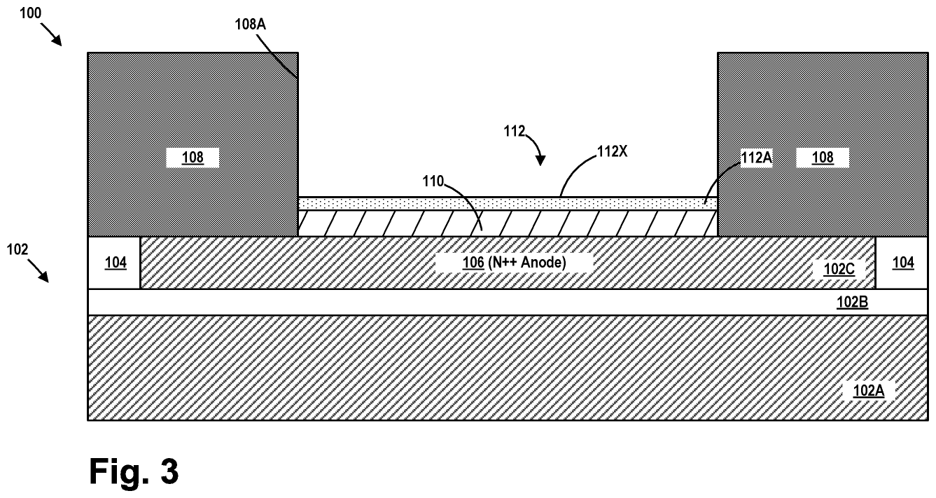

FIG. 3 depicts the photodiode structure 100 after a first portion 112A of a P+ doped charge region 112 was formed above the N+ doped impact ionization region 110. In one illustrative embodiment, the first portion 112A of the P+ doped charge region 112 was formed on and in physical contact with an upper surface of the N+ doped impact ionization region 110. The first portion 112A of the P+ doped charge region 112 may be formed by performing traditional epitaxial semiconductor growth processes and it may formed to any desired thickness, e.g., 10-20 nm. As formed, the first portion 112A of the P+ doped charge region 112 has an upper surface 112X. The first portion 112A of the P+ doped charge region 112 may be comprised of a variety of different materials, e.g., silicon, silicon germanium, etc. In one illustrative process flow, the first portion 112A of the P+ doped charge region 112 may be doped with a P-type dopant as it is grown, i.e., it may be doped in situ. In other applications, the epi semiconductor material for the first portion 112A of the P+ doped charge region 112 may be initially formed as substantially un-doped epi material and thereafter doped with the appropriate dopant atoms by performing one or more ion implantation processes. The maximum concentration of dopant atoms in the first portion 112A of the P+ doped charge region 112 may vary depending upon the particular application, e.g., 1E18-1E20 ions/cm³. The location of the peak concentration of dopant atoms within the vertical thickness of the first portion 112A of the P+ doped charge region 112 may also vary depending upon the particular application. In one illustrative example, the peak concentration of dopant atoms may be located at approximately mid-thickness of the first portion 112A of the P+ doped charge region 112. The first portion 112A of the P+ doped charge region 112 may be doped with any species of P-type dopant, e.g., boron, boron difluoride, etc.

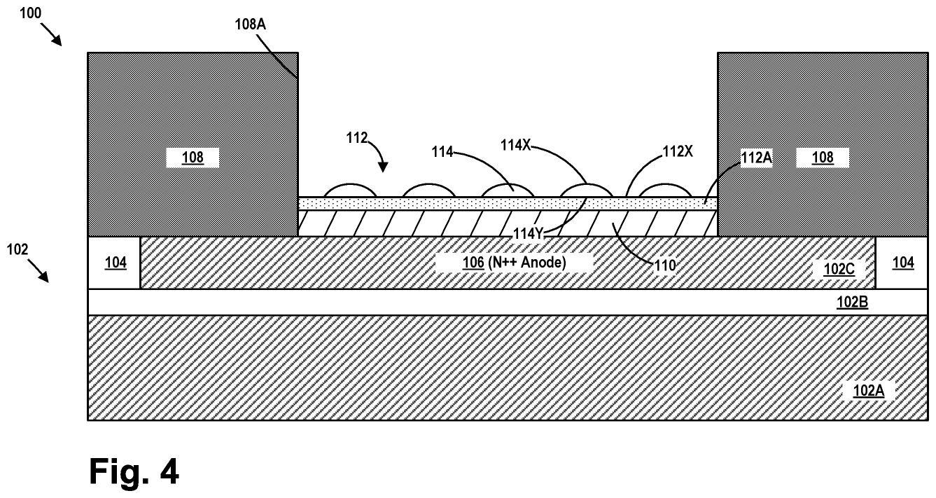

FIG. 4 depicts the photodiode structure 100 after a plurality of quantum dots 114 were formed above the first portion 112A of the P+ doped charge region 112. In one illustrative embodiment, the plurality of quantum dots 114 was formed on and in physical contact with an upper surface 112X of the first portion 112A of the P+ doped charge region 112. In one illustrative embodiment, the plurality of quantum dots 114 may be formed by performing a known Stanski-Krastanov (SK) growth technique. In general, the SK growth process occurs when there is a relatively large mismatch (e.g., 50-100%) between the lattice structures of the two hetero-structure constituent materials. Due to this lattice mismatch, elastic strain energy accumulated in the epi material assists in allowing the plurality of quantum dots 114 to grow. In general, the quantum dots 114 may have any desired configuration when viewed from above, e.g., substantially circular, substantially oval, substantially pyramidal, etc. Additionally the vertical thickness of the quantum dots 114, as measured from the upper surface 114X to the bottom surface 114Y may also vary depending upon the particular application, e.g., 1-10 nm. The lateral spacing between adjacent quantum dots 114 may also vary depending upon the particular application, e.g., 10-100 nm. Lastly, in the case where the quantum dots 114 have a substantially circular pattern when viewed from above, in one illustrative example, the quantum dots 114 may have an approximate diameter of about 5-40 nm.

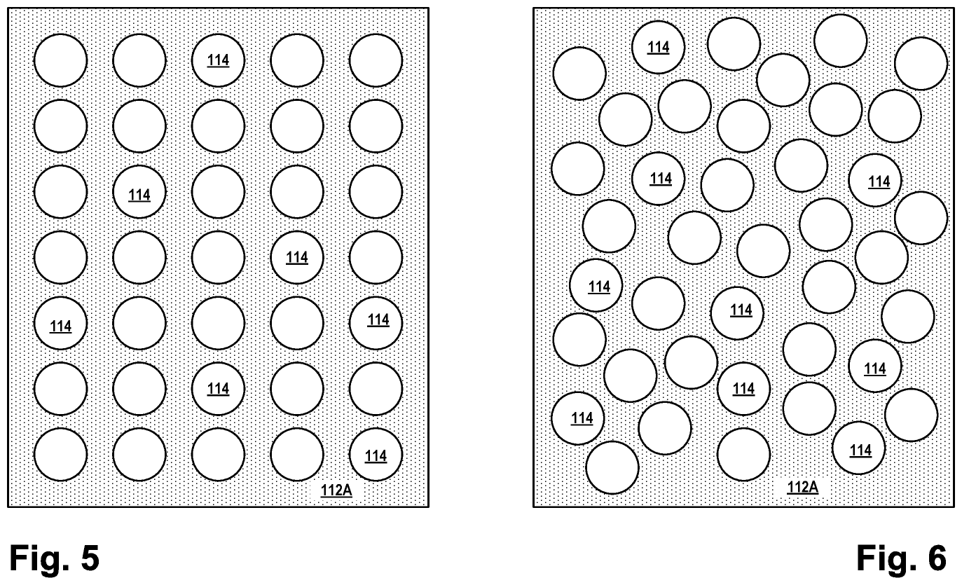

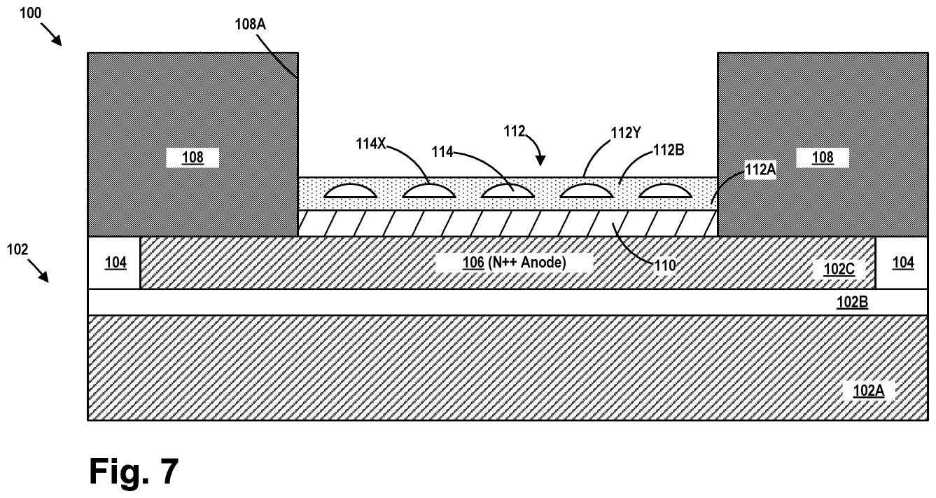

FIG. 5 is a simplistic plan view showing the quantum dots 114 formed in an ordered array of rows and columns. FIG. 6 is a simplistic plan view showing the quantum dots 114 formed in a non-ordered or random pattern. In the case where the photodiode structure 100 comprises a plurality of layers of quantum dots 114 (described more fully below), all of the layers of quantum dots 114 may be formed with an ordered array pattern or all of the layers of quantum dots 114 may be formed with a random pattern. In some cases, all of the ordered layers of quantum dots 114 may have the same ordered pattern, but that may not be the case in all applications. In the case where all of the layers of quantum dots 114 are formed in a random pattern, each layer of quantum dots 114 may be formed with the same random pattern, but that may not be the case in all applications. In even further embodiments where the photodiode structure 100 comprises a plurality of layers of quantum dots 114, the photodiode structure 100 may be formed with one or more layers of quantum dots 114 having an ordered pattern and one or more layers of quantum dots 114 having a random pattern. In some applications, a layer of quantum dots 114 having a random pattern may be positioned vertically between upper and lower layers of quantum dots 114 having a random pattern. The opposite configuration is also possible. In other cases, a first group of layers of quantum dots 114 having a random pattern may be positioned vertically adjacent one another while a second group of layers of quantum dots 114 having an ordered pattern may be positioned vertically adjacent one another, where the first group is positioned vertically below the second group. The opposite configuration is also possible.

The quantum dots 114 may be formed by performing an epitaxial growth process and the quantum dots 114 may be doped or un-doped. In the case where the quantum dots 114 are doped, they may be doped with a P-type dopant or an N-type dopant and they may be doped in situ or by performing an ion implantation process. The maximum concentration of dopant atoms in the quantum dots 114 may vary depending upon the particular application, e.g., 1E14-1E16 ions/cm³ (or they may be an intrinsic material perhaps with a dopant concentration less than 1E14). The location of the peak concentration of dopant atoms within the vertical thickness of the quantum dots 114 may also vary depending upon the particular application. In one illustrative example, the peak concentration of dopant atoms may be located at approximately mid-thickness of the quantum dots 114. The quantum dots 114 may be comprised of a variety of different semiconductor materials, e.g., a silicon-containing semiconductor material, a germanium-containing semiconductor material, silicon germanium, substantially pure silicon, substantially pure germanium, etc. In one illustrative example, where the photodiode structure 100 will be exposed to incident light having a wavelength of 1.5 μm or greater, the quantum dots 114 may be comprised of substantially pure germanium. In another illustrative example, where the photodiode structure 100 will be exposed to incident light having a wavelength of less than 1.5 μm, the quantum dots 114 may be comprised of substantially pure silicon.

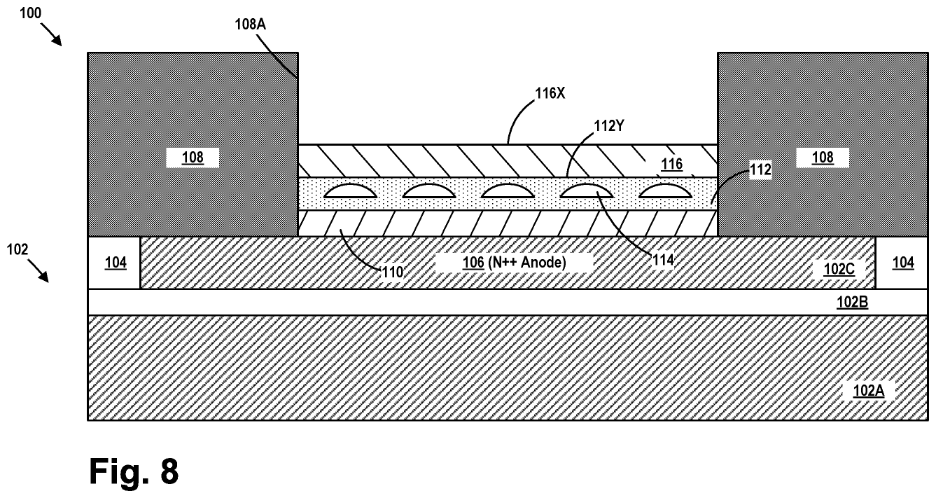

FIG. 7 depicts the photodiode structure 100 after a second portion 112B of the P+ doped charge region 112 was formed above the first portion 112A of the P+ doped charge region 112 and above the quantum dots 114. Note that the upper surface 112Y of the second portion 112B of the P+ doped charge region 112 is positioned above the uppermost surface 114X of the plurality of quantum dots 114. That is, in one illustrative embodiment, the combination of the first portion 112A and the second portion 112B of the P+ doped charge region 112 encapsulates the plurality of quantum dots 114. The distance between the upper surface 112Y of second portion 112B of the P+ doped charge region 112 and the uppermost surface 114X of the quantum dots 114 may vary depending upon the particular application, e.g., 5-30 nm. In one illustrative embodiment, the first portion 112A and the second portion 112B of the P+ doped charge region 112 may be comprised of the same material and may be doped in a similar manner as described above in connection with the first portion of the P+ doped charge region 112, but that may not be the case in all applications. In one illustrative embodiment, the second portion 112B of the P+ doped charge region 112 was formed on and in physical contact with the upper surface 112Y of the first portion 112A of the P+ doped charge region 112. The second portion 112B of the P+ doped charge region 112 may be formed by performing traditional epitaxial semiconductor growth processes and it may be formed to any desired thickness, e.g., 10-100 nm. However, in the case where stacked quantum dots 114 are being formed, it may be desirable that the second portion 112B of the P+ doped charge region 112 may have a lesser thickness, e.g., 5-20 nm. Henceforth, the combination of the first portion 112A and the second portion 112B of the P+ doped charge region 112 may be collectively referred to as the P+ doped charge region 112.

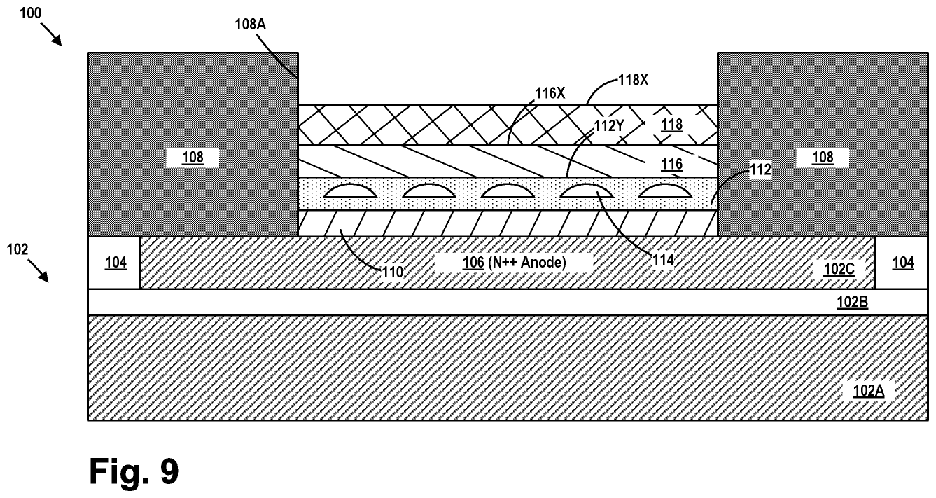

FIG. 8 depicts the photodiode structure 100 after an epitaxial growth process was performed to form an optional substantially un-doped intrinsic semiconductor material layer 116 above the upper surface 112Y of the P+ doped charge region 112. The intrinsic semiconductor material layer 116 may be formed by performing traditional epitaxial semiconductor growth processes and it may be formed to any desired thickness, e.g., 5-50 nm. As formed, the intrinsic semiconductor material layer 116 has an upper surface 116X. The intrinsic semiconductor material layer 116 may be comprised of a variety of different materials, e.g., silicon, silicon germanium, etc.

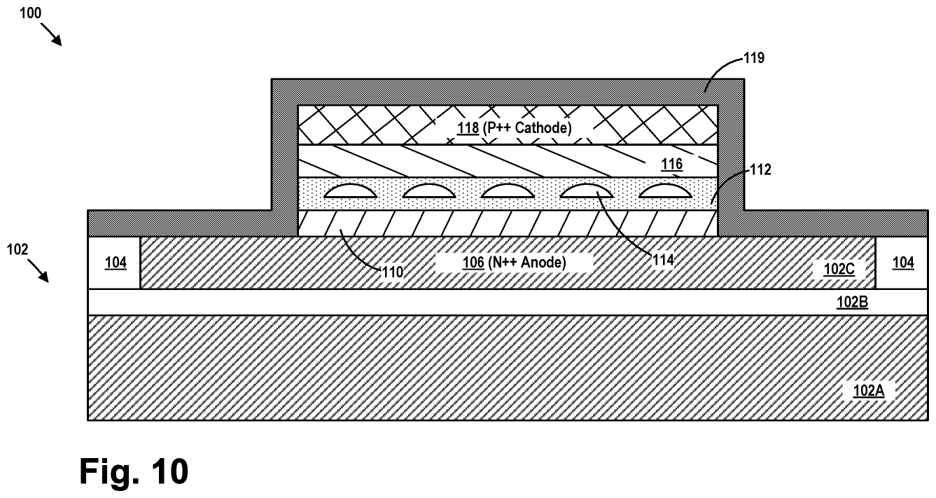

FIG. 9 depicts the photodiode structure 100 after an epitaxial growth process was performed to form a P++ doped anode cathode region 118 above the optional intrinsic semiconductor material layer 116 (or above the P+ doped charge region 112 if the intrinsic semiconductor material layer 116 is omitted). In one illustrative embodiment, the P++ doped anode cathode region 118 was formed on and in physical contact with the upper surface 116X of the intrinsic semiconductor material layer 116 (or on and in physical contact with the upper surface 112Y of the P+ doped charge region 112 if the intrinsic semiconductor material layer 116 is omitted). The P++ doped anode cathode region 118 may be formed by performing traditional epitaxial semiconductor growth processes and it may be formed to any desired thickness, e.g., 5-200 nm. The P++ doped anode cathode region 118 may be comprised of a variety of different materials, e.g., silicon, silicon germanium, etc. In one illustrative process flow, the P++ doped anode cathode region 118 may be doped with a P-type dopant as it is grown, i.e., it may be doped in situ. In other applications, the epi semiconductor material for the P++ doped anode cathode region 118 may be initially formed as substantially un-doped epi material and thereafter doped with the appropriate dopant atoms by performing one or more ion implantation processes. The maximum concentration of dopant atoms in the P++ doped anode cathode region 118 may vary depending upon the particular application, e.g., 1E20-1E23 ions/cm³. The location of the peak concentration of dopant atoms within the vertical thickness of the P++ doped anode cathode region 118 may also vary depending upon the particular application. In one illustrative example, the peak concentration of dopant atoms may be located at approximately mid-thickness of the P++ doped anode cathode region 118. The P++ doped anode cathode region 118 may be doped with any species of P-type dopant, e.g., boron, boron difluoride, etc.

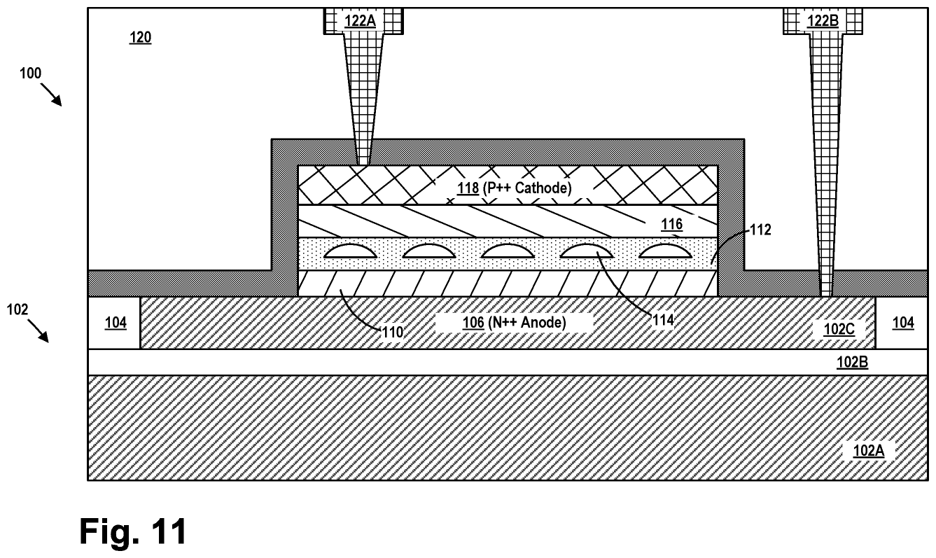

FIG. 10 depicts the photodiode structure 100 after several process operations were performed. First, the patterned mask layer 108 was removed. Then, a passivation material layer 119 was formed above the substrate 102. In one illustrative embodiment, the passivation material layer 119 may be formed by depositing a conformal layer of the passivation material. The passivation material layer 119 may be comprised of a variety of different materials, e.g., silicon nitride, silicon dioxide, silicon oxynitride, etc. Moreover, the passivation material layer 119 may formed to any desired thickness, e.g., nanometers to several micrometers. The passivation material layer 1119 can also be a heterostructure, e.g., comprising SiO₂/SiON/carbon doped porous SiO₂, etc.

FIG. 11 depicts the photodiode structure 100 after several process operations were performed. A simplistically depicted one or more layers of insulating material 120 was formed above the photodiode structure 100. In a real-world device, the one or more layers of insulating material 120 may comprise multiple layers of material and the layers of material may be made of different materials. For example, the one or more layers of insulating material 120 may comprise one of more layers of silicon dioxide with a layer of silicon nitride (which functions as an etch stop layer) positioned between the layers of silicon dioxide. The structure, composition and techniques used to form such layer(s) of insulating material are well known to those skilled in the art. Thereafter, illustrative conductive contact structures 122A, 122B (collectively referenced using the numeral 122) were formed so as to conductively contact the P++ doped anode cathode region 118 and the N++ doped anode region 106, respectively. The structure, composition and techniques used to form such conductive contact structures 122 are well known to those skilled in the art.

As will be appreciated by those skilled in the art after a complete reading of the present application, germanium and silicon are both indirect band gap materials, and thus may be considered to be less than ideal materials for optoelectronics applications. However, the conduction and valence bands are much closer in germanium than in silicon. When germanium is grown on silicon, the germanium has a tensile strain which reduces the bandgap of the germanium material further. Thus, tensile strained germanium quantum dots 114, with a very high level of tensile strain, have a reduced band gap which reduces the direct energy band and improves optoelectronic properties (both detection and lasing) of the germanium material.

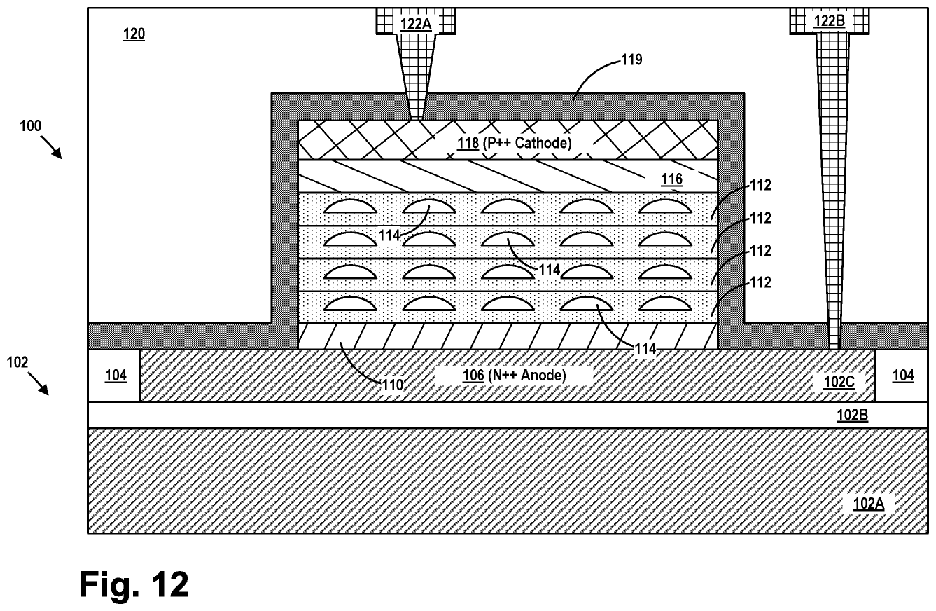

As will be appreciated by those skilled in the art after a complete reading of the present application, the vertically oriented photodiode structure 100 disclosed herein may come in a variety of different configurations. For example, FIG. 12 depicts an embodiment of the photodiode structure 100 that comprises the above-described N++ doped anode region 106, the N+ doped impact ionization region 110, the substantially un-doped intrinsic semiconductor material layer 116 and the P++ doped anode cathode region 118. However, in this illustrative embodiment, the photodiode structure 100 comprises a plurality of P+ doped charge regions 112 positioned vertically between the N+ doped impact ionization region 110 and the substantially un-doped intrinsic semiconductor material layer 116. Also note that, in this embodiment, each of the P+ doped charge regions 112 comprises a plurality of quantum dots 114 embedded therein. In the depicted example, the lowermost P+ doped charge region 112 may be formed on and in physical contact with the upper surface of the N+ doped impact ionization region 110 and the other P+ doped charge regions 112 may be formed on and in physical contact with the underlying P+ doped charge region 112, but such an illustrative configuration may not be required in all applications. In this illustrative example, the substantially un-doped intrinsic semiconductor material layer 116 may be formed on and in physical contact with the upper surface of the uppermost P+ doped charge region 112. However, as noted above, the substantially un-doped intrinsic semiconductor material layer 116 is optional and may not be present in all embodiments. If the substantially un-doped intrinsic semiconductor material layer 116 is omitted, then the P++ doped anode cathode region 118 may be formed on and in physical contact with the upper surface of the uppermost P+ doped charge region 112. The physical characteristics of each of the plurality of P+ doped charge regions 112, e.g., thickness, doping, material, may all be approximately the same in some applications, but that may not be the case in other applications. In the example shown in FIG. 12, the photodiode structure 100 comprises four of the illustrative P+ doped charge regions 112, but the photodiode structure 100 may comprise any desired number of the P+ doped charge regions 112. Lastly, the number of quantum dots 114 within each of the P+ doped charge regions 112 may be approximately equal in some applications, but that may not be the case in all situations. As noted previously, the pattern of the quantum dots 114—ordered or random—may also be different in the P+ doped charge regions 112.

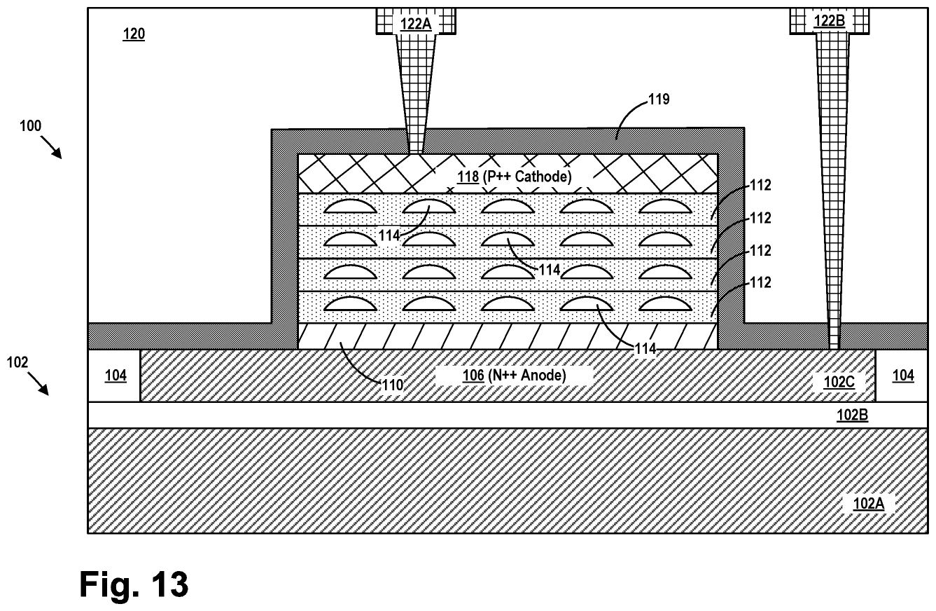

FIG. 13 depicts an embodiment of the photodiode structure 100 that is substantially similar to the embodiment of the photodiode structure 100 shown in FIG. 12. However, in the embodiment shown in FIG. 13, the substantially un-doped intrinsic semiconductor material layer 116 has been omitted and the P++ doped anode cathode region 118 may be formed on and in physical contact with the upper surface of the uppermost P+ doped charge region 112.

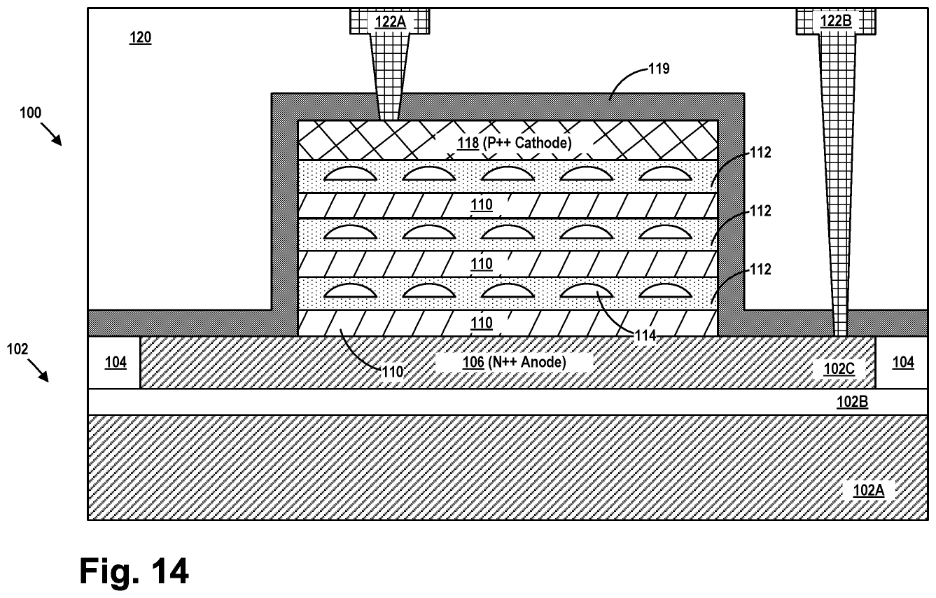

FIG. 14 depicts an embodiment of the photodiode structure 100 that comprises the above-described N++ doped anode region 106, a plurality (e.g., three) of the N+ doped impact ionization regions 110, a plurality (e.g., three) of the P+ doped charge regions 112, and the P++ doped anode cathode region 118. In the embodiment shown in FIG. 14, the substantially un-doped intrinsic semiconductor material layer 116 has been omitted and the P++ doped anode cathode region 118 may be formed on and in physical contact with the upper surface of the uppermost P+ doped charge region 112. In this example, the lowermost N+ doped impact ionization region 110 separates the lowermost P+ doped charge region 112 from the N++ doped anode region 106; the middle N+ doped impact ionization region 110 separates the middle P+ doped charge region 112 from the lowermost P+ doped charge region 112 and the uppermost N+ doped impact ionization region 110 separates the uppermost P+ doped charge region 112 from the middle P+ doped charge region 112. Also note that, as before, in this embodiment, each of the P+ doped charge regions 112 comprises a plurality of quantum dots 114 embedded therein as described above.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Note that the use of terms, such as “first,” “second,” “third” or “fourth” to describe various processes or structures in this specification and in the attached claims is only used as a shorthand reference to such steps/structures and does not necessarily imply that such steps/structures are performed/formed in that ordered sequence. Of course, depending upon the exact claim language, an ordered sequence of such processes may or may not be required. Accordingly, the protection sought herein is as set forth in the claims below.

1. A photodiode, comprising:
an N-doped anode region;
an N-doped impact ionization region positioned above the N-doped anode region;
at least one P-doped charge region positioned above the N-doped impact ionization region;
a plurality of quantum dots embedded within the at least one P-doped charge region; and
a P-doped cathode region positioned above the at least one P-doped charge region.

2. The photodiode of claim 1, further comprising a semiconductor-on-insulator (SOI) that comprises a base semiconductor layer, a buried insulation layer positioned on the base semiconductor layer and an active semiconductor layer positioned on the buried insulation layer, wherein the N-doped anode region is positioned within the active semiconductor layer and wherein the N-doped anode region has a dopant concentration of an N-type dopant that falls within a range of 1E20-1E23 ions/cm³, the N-doped impact ionization region comprises silicon and has a dopant concentration of an N-type dopant that falls within a range of 1E18-1E20 ions/cm³, the at least one P-doped charge region comprises silicon and has a dopant concentration of a P-type dopant that falls within a range of 1E18-1E20 ions/cm³, and the P-doped cathode region comprises silicon and has a dopant concentration of P-type dopant that falls within a range of 1E20-1E23 ions/cm³.

3. The photodiode of claim 1, wherein at least one P-doped charge region comprises a plurality of P-doped charge regions, wherein each of the plurality of P-doped charge regions comprises a plurality of quantum dots embedded therein.

4. The photodiode of claim 1, wherein, when viewed from above, the plurality of quantum dots embedded within the at least one P-doped charge region have one of an ordered pattern or a random pattern and one of a substantially circular, a substantially oval or a substantially pyramidal configuration.

5. The photodiode of claim 1, wherein the plurality of quantum dots embedded within the at least one P-doped charge region are doped with a P-type dopant.

6. The photodiode of claim 1, wherein the plurality of quantum dots embedded within the at least one P-doped charge region comprise one of a silicon-containing semiconductor material, a germanium-containing semiconductor material, silicon germanium, substantially pure silicon or substantially pure germanium.

7. The photodiode of claim 1, further comprising a substantially un-doped intrinsic semiconductor material layer positioned above the at least one P-doped charge region and below the P-doped cathode region.

8. The photodiode of 1, wherein the N-doped impact ionization region is positioned on and in physical contact with an upper surface of the N-doped anode region, the at least one P-doped charge region is positioned on and in physical contact with an upper surface of the N-doped impact ionization region and the P-doped cathode region is positioned above an upper surface of the at least one P-doped charge region.

9. The photodiode of claim 1, wherein the at least one P-doped charge region comprises a single P-doped charge region, wherein the single P-doped charge region comprises the plurality of quantum dots embedded therein and wherein the photodiode further comprises a substantially un-doped intrinsic semiconductor material layer positioned on and in physical contact with an upper surface of the single P-doped charge region, the single P-doped charge region is positioned on and in physical contact with an upper surface of the N-doped impact ionization region and the P-doped cathode region is positioned on and in physical contact with an upper surface of the substantially un-doped intrinsic semiconductor material.

10. The photodiode of claim 1, wherein the at least one P-doped charge region comprises a plurality of P-doped charge regions, wherein each of the plurality of P-doped charge regions comprises a plurality of quantum dots embedded therein and wherein the photodiode further comprises a substantially un-doped intrinsic semiconductor material layer positioned on and in physical contact with an upper surface of an uppermost of the plurality of P-doped charge regions, a lowermost of the plurality of P-doped charge regions is positioned on and in physical contact with an upper surface of the N-doped impact ionization region and the P-doped cathode region is positioned on and in physical contact with an upper surface of the substantially un-doped intrinsic semiconductor material.

11. The photodiode of claim 1, wherein the at least one P-doped charge region comprises a plurality of P-doped charge regions, wherein each of the plurality of P-doped charge regions comprises a plurality of quantum dots embedded therein and wherein the P-doped cathode region is positioned on and in physical contact with an upper surface of an uppermost of the plurality of P-doped charge regions and a lowermost of the plurality of P-doped charge regions is positioned on and in physical contact with an upper surface of the N-doped impact ionization region.

12. The photodiode of claim 1, wherein the at least one P-doped charge region comprises a plurality of P-doped charge regions, wherein each of the plurality of P-doped charge regions comprises a plurality of quantum dots embedded therein and wherein the photodiode further comprises a second N-doped impact ionization region, wherein a first of the plurality of P-doped charge regions is positioned above an upper surface of the N-doped impact ionization region, the second N-doped impact ionization region is positioned above an upper surface of the first of the plurality of P-doped charge regions, a second of the plurality of P-doped charge regions is positioned above an upper surface of the second N-doped impact ionization region and the P-doped cathode region is positioned above an upper surface of the second of the plurality of P-doped charge regions.

13. The photodiode of claim 1, wherein the plurality of quantum dots have a tensile strain.

14. A photodiode, comprising:
a semiconductor-on-insulator (SOI) that comprises a base semiconductor layer, a buried insulation layer positioned on the base semiconductor layer and an active semiconductor layer positioned on the buried insulation layer;
an N-doped anode region positioned within the active semiconductor layer;
a first N-doped impact ionization region positioned on and in physical contact with an upper surface of the N-doped anode region;
a P-doped cathode region positioned above the first N-doped impact ionization region;
at least one P-doped charge region positioned above an upper surface of the first N-doped impact ionization region and below a bottom surface of the P-doped cathode region; and
a plurality of germanium quantum dots embedded within the at least one P-doped charge region, wherein each of the germanium quantum dots has a tensile strain.

15. The photodiode of claim 14, wherein at least one P-doped charge region comprises a plurality of P-doped charge regions, wherein the plurality of P-doped charge regions are positioned above the upper surface the N-doped impact ionization region and below the bottom surface of the P-doped cathode region, wherein each of the plurality of P-doped charge regions has a plurality of quantum dots embedded therein.

16. The photodiode of claim 14, further comprising a substantially un-doped intrinsic semiconductor material layer positioned above the at least one P-doped charge region and below the bottom surface of the P-doped cathode region, wherein the P-doped cathode region is positioned on and in physical contact with an upper surface of the substantially un-doped intrinsic semiconductor material layer.

17. The photodiode of 14, wherein the N-doped impact ionization region is positioned on and in physical contact with an upper surface of the N-doped anode region, the at least one P-doped charge region is positioned on and in physical contact with an upper surface of the N-doped impact ionization region and the P-doped cathode region is positioned above an upper surface of the at least one P-doped charge region.

18. The photodiode of claim 14, wherein the at least one P-doped charge region comprises a single P-doped charge region, wherein the single P-doped charge region comprises the plurality of quantum dots embedded therein and wherein the photodiode further comprises a substantially un-doped intrinsic semiconductor material layer positioned on and in physical contact with an upper surface of the single P-doped charge region, the single P-doped charge region is positioned on and in physical contact with an upper surface of the N-doped impact ionization region and the P-doped cathode region is positioned on and in physical contact with an upper surface of the substantially un-doped intrinsic semiconductor material.

19. The photodiode of claim 14, wherein the at least one P-doped charge region comprises a plurality of P-doped charge regions, wherein each of the plurality of P-doped charge regions comprises a plurality of quantum dots embedded therein and wherein the photodiode further comprises a substantially un-doped intrinsic semiconductor material layer positioned on and in physical contact with an upper surface of an uppermost of the plurality of P-doped charge regions, a lowermost of the plurality of P-doped charge regions is positioned on and in physical contact with an upper surface of the N-doped impact ionization region and the P-doped cathode region is positioned on and in physical contact with an upper surface of the substantially un-doped intrinsic semiconductor material.

20. The photodiode of claim 14, wherein the at least one P-doped charge region comprises a plurality of P-doped charge regions, wherein each of the plurality of P-doped charge regions comprises a plurality of quantum dots embedded therein and wherein the photodiode further comprises a second N-doped impact ionization region, wherein a first of the plurality of P-doped charge regions is positioned above an upper surface of the first N-doped impact ionization region, the second N-doped impact ionization region is positioned above an upper surface of the first of the plurality of P-doped charge regions, a second of the plurality of P-doped charge regions is positioned above an upper surface of the second N-doped impact ionization region and the P-doped cathode region is positioned above an upper surface of the second of the plurality of P-doped charge regions.
